(19) United States
(12) Patent Application Publication
(10) Pub. No.: US 2018/0330842 A1
(43) Pub. Date: Nov. 15, 2018

(54) LAYERED METAL-GRAPHENE-METAL LAMINATE STRUCTURE

(71) Applicant: The Trustees of Columbia University in the City of New York, New York, NY (US)

(72) Inventors: Shruti Rastogi, New York, NY (US); Jeffrey Kysar, New York, NY (US)

(21) Appl. No.: 15/980,398

(22) Filed: May 15, 2018

Related U.S. Application Data
(60) Provisional application No. 62/506,402, filed on May 15, 2017.
(60) Provisional application No. 62/518,844, filed on Jun. 13, 2017.

(51) Int. Cl. H01B 1/04; H01B 1/02

(52) U.S. Cl. CPC H01B 1/04; C23C 14/0605; H01B 1/02

(57) ABSTRACT

A layered metal -graphene-metal nanolaminate electrical connector with improved wear performance and reduced friction. An electrical connector has a chemical vapor deposition (CVD) monolayer graphene sheet sandwiched between two copper layers resulting in a decrease in friction of coefficient and an improvement in wear resistance of an electrical contact.

### CROSS REFERENCE TO RELATED APPLICATIONS

This Non-provisional Application claims priority from U.S. Provisional Application No. 62/506,402, filed May 15, 2017, and U.S. Provisional Application No. 62/518,844, filed Jun. 13, 2017, both of which are incorporated by reference in their entirety herein.

### STATEMENT REGARDING FEDERALLY SPONSORED RESEARCH OR DEVELOPMENT

This invention was made with government support under grant 1363093 awarded by the NSF. The government has certain rights in the invention.

### FIELD OF THE DISCLOSED SUBJECT MATTER

The subject matter pertains generally to laminate structures and the field of electrical connectors and methods of manufacturing electrical connectors.

### BACKGROUND OF THE DISCLOSED SUBJECT MATTER

Electrical connectors can have many forms and applications. Copper and copper alloys are the most widely used base materials for electrical connectors used in switches and brushes. These electrical connectors experience wear due to the mating of contacts and mechanical vibration, thus limiting their longevity. It is known from the study of tribology that a hard material is more wear resistant than a soft material.

It is desirable to develop additional materials for improving the wear properties of electrical connectors while not reducing electrical conductivity.

### SUMMARY OF THE DISCLOSED SUBJECT MATTER

Provided herein is a layered metal-graphene-metal nanolaminate electrical connector with improved wear performance and reduced friction. Provided is a laminate or electrical connector having a chemical vapor deposition (CVD) monolayer graphene sheet sandwiched between two copper layers resulting in a decrease in friction of coefficient and an improvement in wear resistance of an electrical contact.

Provided is a laminate comprising: a base layer comprising copper; a graphene monolayer disposed on the base layer; and a top layer comprising copper disposed on the graphene monolayer; wherein the laminate exhibits a reduced coefficient of friction in comparison to a copper-copper laminate without a graphene monolayer.

Embodiments of this laminate include:

The laminate wherein the top layer has a thickness from 50 to 500 nm.

The laminate further comprising an additional graphene monolayer disposed on the top layer and an additional copper layer disposed on the additional graphene monolayer.

The laminate further comprising one or more additional substrate layers on which the copper base layer is superimposed.

Also provided is a laminate comprising n graphene monolayers and n+1 copper layers, wherein the graphene monolayers alternate with the copper layers, and n is an integer from 1 to 10.

Embodiments of this laminate include:

The laminate wherein one of the copper layers comprises a thicker substrate layer, and the rest of the copper layers are nanolayers, each independently having a thickness from 50 to 500 nm.

The laminate wherein the substrate layer is a surface layer.

The laminate wherein the substrate layer is the center layer of the laminate.

The laminate comprising at least one additional layer.

Embodiments of either laminate include:

The laminate wherein additional substrate layers comprises a bulking or backing layer wherein the base layer of copper has a thickness from 50 to 500 nm.

The laminate wherein the one or more additional substrate layer comprises a material selected from the group consisting of a metal other than copper, nonconductive materials, or semiconductor materials.

The laminate in the form of a sheet.

The laminate in the form of a three-dimensional shaped object.

The laminate used as an electrical connector.

The laminate wherein the laminate comprises a portion of an electrical circuit.

The laminate wherein the laminate comprises a portion of microcircuit.

The laminate wherein the laminate comprises a portion of a microchip.

The laminate in electrical connectivity to one or more other electrical components to provide a circuit; including wherein the circuit comprises a microcircuit.

The laminate wherein a first laminate is disposed in electrical connectivity with a second laminate of different configuration from the first laminate to provide a portion of an electrical circuit; including the laminate wherein the first and second laminates are in the form of sheets; or the laminate wherein a first shaped laminate is disposed in electrical connectivity with a second shaped laminate of different shape from the first shaped laminate to provide a portion of an electrical circuit.

In one embodiment, the laminate structure is fabricated by growing a continuous monolayer graphene on a copper substrate via chemical vapor deposition process. A thin layer of copper is deposited via physical vapor deposition on the grown graphene to synthesize a Cu-Graphene-Cu laminate.

Also provided is a method for preparing the laminates described above, the method comprising providing a base layer comprising copper; disposing a graphene monolayer on the base layer; and disposing a top layer comprising copper on the graphene monolayer.

Embodiments of the method include:

The method wherein disposing the graphene monolayer on the base layer comprises chemical vapor deposition of carbon atoms on the base layer.

The method wherein disposing the top layer comprising copper on the graphene monolayer comprises physical vapor deposition of copper atoms on the graphene monolayer.

The method further comprising electropolishing the base layer prior to disposing the graphene monolayer on the base layer.

The method further comprising sequentially disposing at least one additional graphene monolayer on the top layer; and disposing at least one additional layer comprising copper on the at least one additional graphene monolayer to provide a laminate comprising alternating graphene monolayer and copper layers on the base layer.

Also provided is a method for improving the wear performance or reducing friction of an electrical connector, the method comprising providing a base layer comprising a copper electrical connector; disposing a graphene monolayer on the base layer; and disposing a top layer comprising copper on the graphene monolayer.

Embodiments of the method include:

The method wherein disposing the graphene monolayer on the base layer comprises chemical vapor deposition of carbon atoms on the base layer.

The method wherein disposing the top layer comprising copper on the graphene monolayer comprises physical vapor deposition of copper atoms on the graphene monolayer.

The method further comprising electropolishing the base layer prior to disposing the graphene monolayer on the base layer.

The method further comprising sequentially disposing at least one additional graphene monolayer on the top layer; and disposing at least one additional layer comprising copper on the at least one additional graphene monolayer to provide a laminate comprising alternating graphene monolayer and copper layers on the base layer.

Experiments demonstrate that graphene incorporated into the contact improves the reliability of the electrical connectors while reducing wear and failure.

### BRIEF DESCRIPTION OF THE DRAWINGS

FIGS. 1A and 1B show aspects of damage to electrical devices due to corrosion and wear.

FIG. 2A shows schematically a nano-indentation measurement technique for determining mechanical properties of thin sheets.

FIG. 2B shows a comparison of a graphene-coated copper sheet to uncoated copper and copper coated with a silver-nickel corrosion metal coating.

FIGS. 3A-3C show aspects of graphene providing lubrication of graphene-coated sheets.

FIG. 4 shows a comparison of a graphene metal matrix composite with a laminate in accordance with some implementations of this disclosure.

FIGS. 5A-5C show aspects of the mechanical properties of a laminate in accordance with some implementations of this disclosure.

FIGS. 6A-6D show aspects of fabrication methods in accordance with some implementations of this disclosure.

FIGS. 7A and 7B show aspects of a scratch test method for measuring the frictional properties of a composite in accordance with some implementations of this disclosure.

FIGS. 8A-8C show graphs comparing results of scratch test on a graphene-free Cu—Cu laminate and a Cu-Gr-Cu laminate in accordance with some implementations of this disclosure.

FIGS. 9A and 9B show aspects of a scratch test conducted along the face orientation compared to the edged orientation of a Berkovich tip on a Cu-Gr-Cu laminate in accordance with some implementations of this disclosure.

FIGS. 10A and 10B show aspects of a comparison of the wear properties of a graphene-free copper substrate, a graphene-coated copper substrate and a Cu-Gr-Cu laminate in accordance with some implementations of this disclosure.

FIGS. 11A-D shows graphs illustrating the load displacement curves for a series of shallow indents at (a) 60 nm, (b) 130 nm, (c) 160 nm, (d) 180 nm in accordance with some implementations of this disclosure.

FIGS. 12A-C show aspects of Young's modulus and hardness for a series of shallow indents in a Cu-Gr-Cu laminate in accordance with some implementations of this disclosure.

### DETAILED DESCRIPTION OF THE DISCLOSED SUBJECT MATTER

Described herein are materials and methods for improving the wear performance of electrical contacts and connectors.

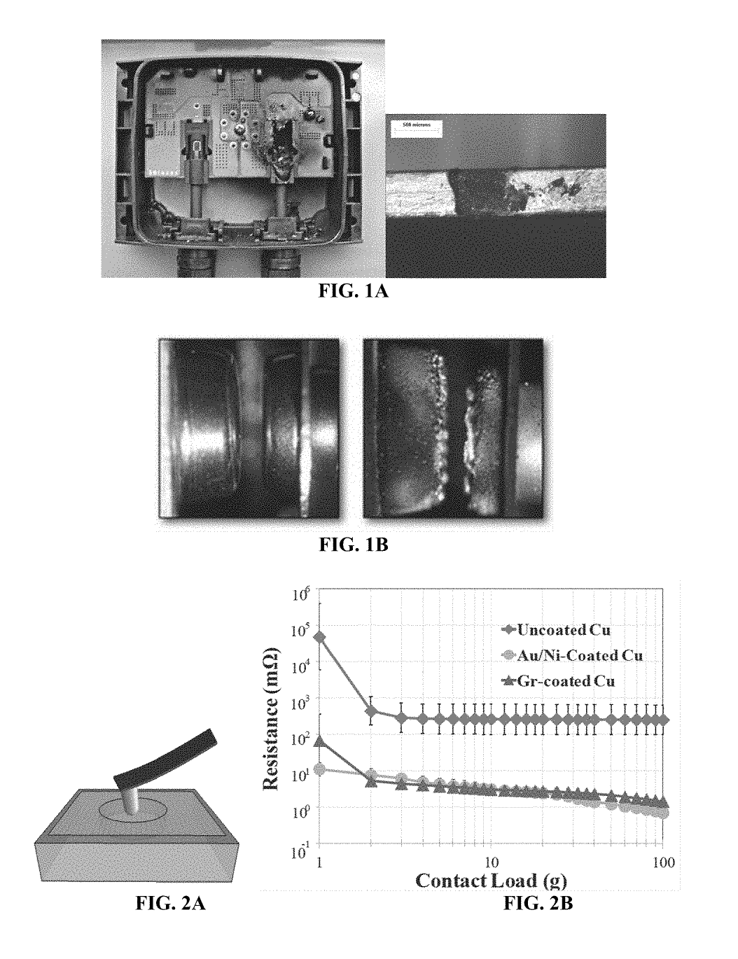

Copper (Cu) and copper alloys are the most widely used base material for electrical contacts and connectors. As shown in FIG. 1A, corrosion and oxidation can build up on the surface of the connector, leading to high resistance and thermal damage. Wear is the progressive loss of material during relative motion between a surface and the contacting substance or substances. Wear can lead to improper interaction between the mating surfaces of electrical contacts and connectors, as shown in FIG. 1B. The combination of corrosion/oxidation and wear can limit the usable lifetime of these connectors. Metal matrix composites (MMCs) have been examined as a way to reduce wear in electrical connectors by providing harder materials. The basic tribological parameters that can control the wear and friction behavior of metal matrix composites (MMCs) include material, mechanical, and physical factors. Material factors include the mechanical properties of the material/composite, the type of reinforcement, reinforcement size, shape of the reinforcement, reinforcement volume fraction and the microstructure of the matrix. Mechanical factors include the normal load, sliding velocity and sliding distance. Physical factors include temperature and other environmental conditions. However, the poor conductivity of oxides and carbide nanoparticles makes them undesirable as a reinforcement choice for electronic applications. They improve hardness but increase resistivity. Protective coatings are thin and can wear easily, and may also be less conductive than their underlying copper substrate. Alternatives to conventional MMCs are needed.

An alternative material may involve graphene. Graphene (abbreviated Gr) is a two-dimensional material consisting of an atomically thin sheet of carbon atoms covalently bonded in a honeycomb (hexagonal) lattice. Graphene exhibits exceptional mechanical properties. It is the strongest material in the world, with a maximum strength of 100 GPa. This is demonstrated through the nano-indentation of free-standing circular membranes. FIG. 2A shows schematically a nano-indentation measurement technique for determining mechanical properties of thin sheets such as Young's modulus and tensile strength. It involves nano-indentation of a freely suspended graphene membrane or other composite membranes. Pure graphene sheets were measured to have a 2D Young's modulus of 340 N/m and tensile strength of 34.5 N/m. Graphene also has excellent conductivity. FIG. 2B shows a comparison of a graphene-coated copper sheet to uncoated copper and copper coated with a silver-nickel corrosion metal coating. The graphene-coated sheet has contact resistance two orders of magnitude lower than the corrosion metal-coated sheet and comparable to uncoated copper. It is also impermeable to gases, so it can prevent corrosion while not increasing resistivity.

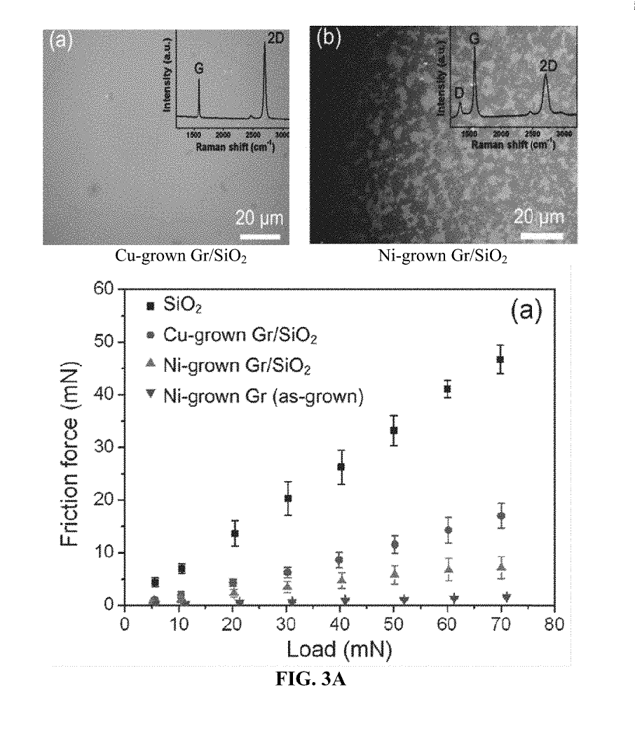

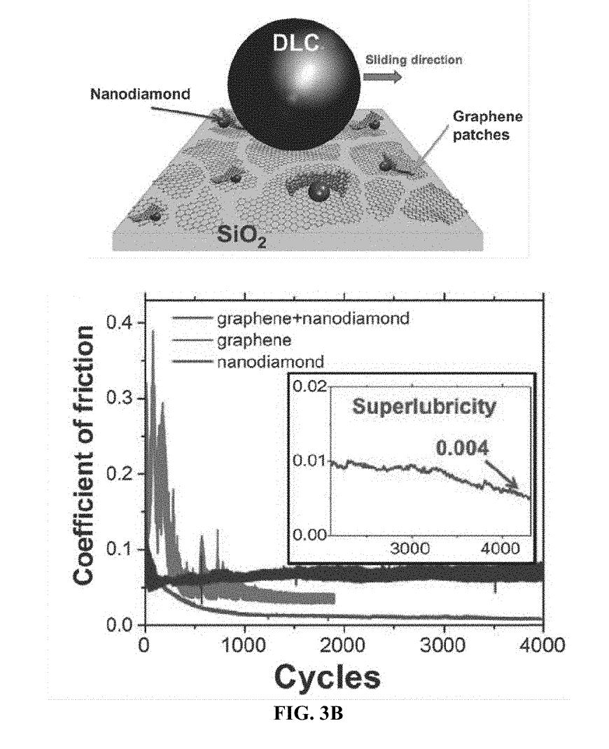

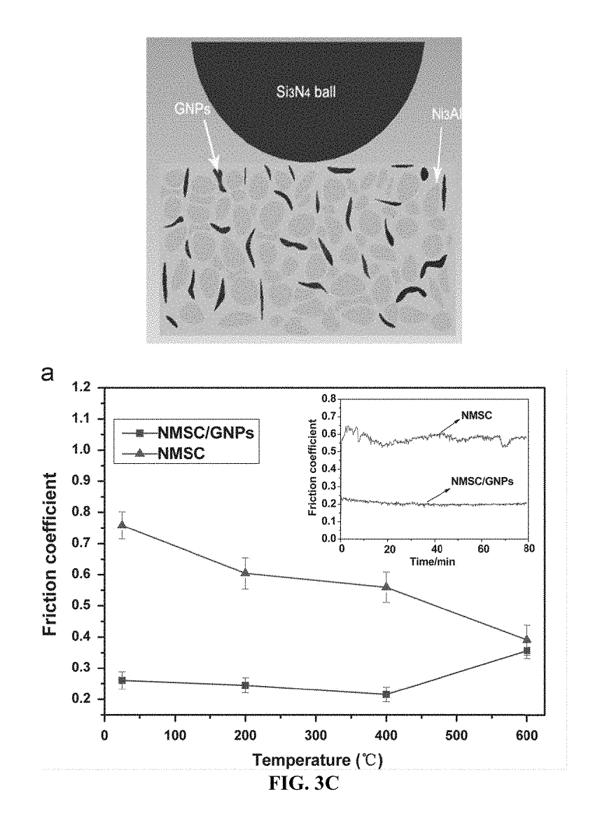

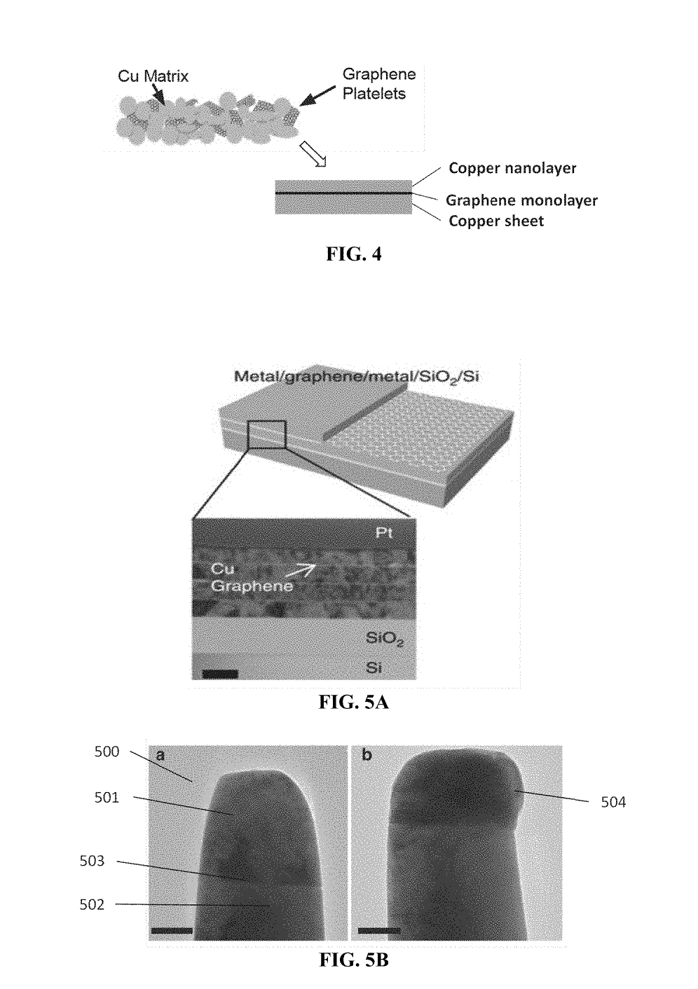

Graphene also acts as a solid lubricant to reduce wear. FIG. 3A shows a comparison of several coatings grown on copper or nickel sheets by chemical vapor deposition (CVD) of SiO₂, graphene/SiO₂ or pure graphene. Friction tests were performed using a fused silica lens to scratch the surface of the sheets. Pure graphene provided excellent (low) friction force over a range of loads. Superlubricity can be achieved as shown schematically in FIG. 3B wherein graphene platelets encapsulate nanodiamonds to form nano-sized ball bearings. The graph shows the coefficient of friction over repeated cycles. Aspects of suppressing wear in graphene-Ni₃Al composites are shown in FIG. 3C, with the graph showing a lower friction coefficient when graphene nanoparticles (GNPs) are included in the composite.

A matrix composite of graphene platelets in a metal (Cu) matrix is shown schematically in FIG. 4. The matrix can result in poor strength enhancement due to non-uniform dispersion of graphene flakes in the matrix and the low mechanical strength of graphene oxide that may be present in the matrix. A structure comprising alternating monolayers of graphene and nanolayers of copper is a better microstructure for wear enhancement. The structure provides improved interaction between copper and graphene, providing an improvement in mechanical properties.

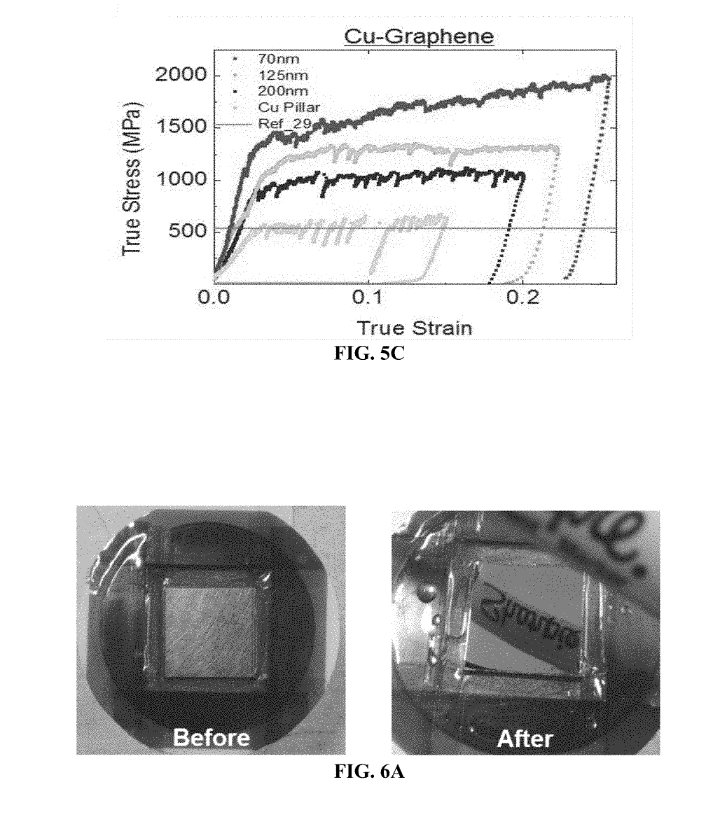

A structure such as shown in FIG. 5A can create an ultra-strong composite having strength of 1.5 GPa. A compression test of a nano-pillar 500 comprising a copper nanolayer tip 501 on a substrate layer of copper 502 separated by a graphene monolayer 503 shows that accumulated or piled-up dislocations of copper along the graphene monolayer interface can escape to the free surface of the nano-pillar, resulting in a lateral bulge 504 of the copper at the tip (FIG. 5B). FIG. 5C shows a graph of stress vs. strain of various sizes of layered nano-pillars compared to a pure copper nano-pillar. The copper graphene nano-pillars exhibited larger stress-strain envelopes than the pure copper nano-pillar.

Provided herein is a laminate having a chemical vapor deposition (CVD) monolayer graphene sheet sandwiched between two copper layers resulting in a decrease in friction of coefficient and an improvement in wear resistance of the laminate compared to structures without an embedded graphene layer. In one embodiment the laminate is used as an electrical connector.

Chemical vapor deposition (CVD) can be used to prepare monolayer (one atom thick) graphene on substrates in an industrially scalar method. CVD facilitates the growth of large areas of graphene that conforms to a metal substrate of choice such as copper. CVD is conducted by passing methane through a quartz tube equipped with gas inlets at high heat where the methane reacts to provide atomic carbon, which is deposited on the substrate. The resulting graphene film is polycrystalline and may have defects in the form of a one dimensional grain boundary such as bilayer or trilayer patches. CVD of the graphene may be conducted at temperatures from about 800° C. to about 1200° C. for about 15 to 45 minutes. Shorter CVD periods may result in gaps in the monolayer and longer periods may increase the incidence of bilayer, trilayer and multilayer patch defects in the graphene sheet. A second copper layer can be deposited onto the graphene layer by physical vapor deposition, such as by sputtering, in nanolayer thickness, such as from about 50 to about 500 nm, or from about 100 nm to 400 nm.

Physical vapor deposition (PVD) includes a variety of vacuum deposition methods that can be used to produce thin films and coatings. PVD is characterized by a process in which the material goes from a condensed phase to a vapor phase and then back to a thin film condensed phase. The most common PVD processes are sputtering and evaporation. Examples of PVD include cathodic arc deposition, in which a high-power electric arc discharged at a target (source) material blasts away some into highly ionized vapor to be deposited onto the workpiece; electron beam physical vapor deposition, in which the material to be deposited is heated to a high vapor pressure by electron bombardment in high vacuum and is transported by diffusion to be deposited by condensation on the (cooler) workpiece; evaporative deposition in which the material to be deposited is heated to a high vapor pressure by electrical resistance heating in high vacuum; pulsed laser deposition in which a high-power laser ablates material from a target into a vapor for subsequent deposition; and sputter deposition, in which a glow plasma discharge (usually localized around a source target by a magnet) bombards the material, sputtering some away as a vapor for subsequent deposition; and pulsed electron deposition, in which a highly energetic pulsed electron beam ablates material from the source target generating a plasma stream under nonequilibrium conditions.

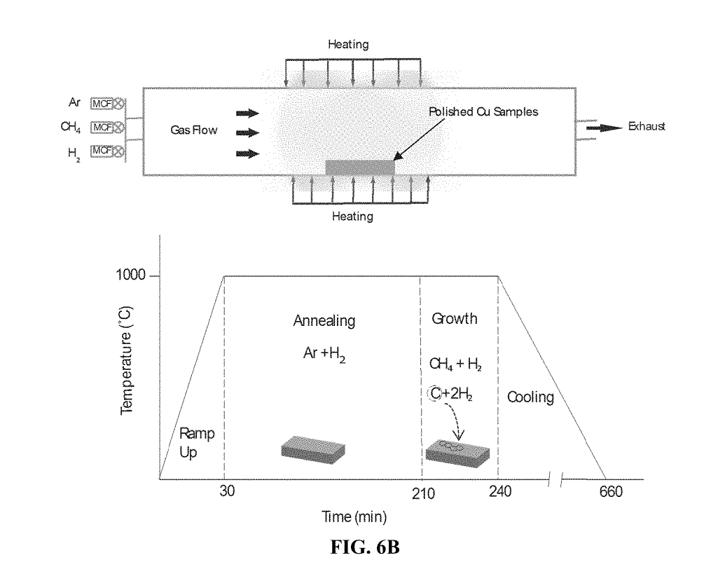

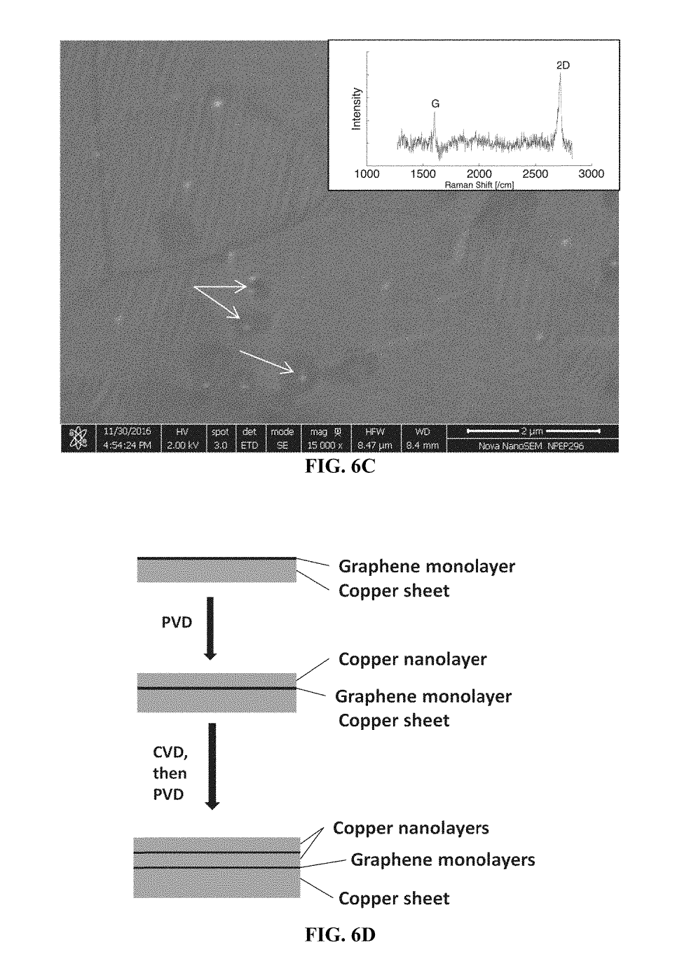

A flow scheme of the fabrication of the fabrication process is shown in FIGS. 6A-D. Fabrication of the composite involves electropolishing of the copper substrate or base layer prior to CVD of the graphene. Electropolishing of the base layer, such as a 1-mm thick sheet, reduces surface roughness to less than 2 nm. FIG. 6A shows how electropolishing provides a mirror-like surface on the copper. As shown in FIG. 6B, the polished copper sheet is placed in the CVD apparatus and the temperature is ramped up to 1000° C. in about 30 minutes, followed by an annealing period where Argon and H₂ are passed through the apparatus for about 180 minutes. Growth of the graphene layer is conducted by flowing methane and H₂ through the CVD apparatus for about 30 minutes at 1000° C. During the growth process, the methane and hydrogen react to provide atomic carbon, which is deposited onto the copper substrate. The graphene-Cu layered structure is cooled back to ambient temperature over a period of several hours, for example 7 hours. FIG. 6C shows a scanning electron micrograph of a CVD graphene monolayer surface prepared in this way, showing only small bilayer patches indicated by arrows. A second copper layer is sputtered onto the graphene layer by physical vapor deposition (FIG. 6D). The second copper layer is a nanolayer and may have a thickness from about 50 to about 500 nm, such as about 100 nm.

The result is a three-layer laminate comprising a graphene monolayer sandwiched between two copper layers, at least one of which is a nanolayer having thickness from about 50 nm to about 500 nm.

The 3-step fabrication process can be repeated to provide additional graphene monolayer(s) and copper nanolayer(s) in the laminate. For instance, repeating the process one additional time provides a 5-layer laminate as shown in FIG. 6D. The process can be carried out n times to provide a laminate comprising n graphene monolayers and n+1 copper layers, wherein the graphene monolayers alternate with the copper layers, such as wherein n is an integer from 1 to 10. One of the copper layers may be a thicker substrate layer, and the rest are nanolayers each independently having a thickness from 50 to 500 nm. The thickness of the nanolayers may be the same or different. In one embodiment, the substrate layer comprises a surface layer. In another embodiment, the substrate layer comprises the center layer of the laminate.

In some embodiments, the laminate may further comprise one or more additional substrate layers on which the copper substrate or base layer is superimposed. The additional substrate layers may comprise a bulking or backing layer that allows the first copper layer to be thinner. For example, a layer of copper can be sputtered onto an additional substrate layer to provide a nanolayer of copper on the additional substrate layer. The additional substrate layer(s) may comprise a metal other than copper, such as gold, silver, platinum, steel, etc., nonconductive (insulating) materials, or semiconductor materials. The substrate may comprise silicon and/or silicon dioxide. The additional substrate layer may be a sacrificial layer that is not included in the final laminate, or it may be included in the final laminate.

The embodiments shown in the figures are shown schematically in the form of sheets, but the laminate is not limited to sheets. In some embodiments, the substrate and the resulting laminate may be a three-dimensional shaped object. The shaped object may be molded, machined, 3D printed or otherwise shaped to provide the desired shape. The shaped object may comprise a conventional metal (copper) electrical connector of any desired shape to match its intended use in an electrical circuit or device. Provided is a method for improving the wear performance or reducing friction of an electrical connector, the method comprising providing a base layer comprising a copper electrical connector; disposing a graphene monolayer on the base layer; and disposing a top layer comprising copper on the graphene monolayer. Application of a graphene monolayer and a nanolayer of copper as described herein can provide additional wear prevention to the connector without adding significant thickness or reducing conductivity.

The Cu-Gr-Cu laminates described herein may be particularly suitable for use in microcircuits, such as in microchips. An initial copper nanolayer may be applied by PVD, such as by sputtering, onto a substrate layer, followed by application of a graphene monolayer by CVD and a copper nanolayer by PVD as described herein. Additional graphene monolayer(s) and copper nanolayer(s) may be applied to provide multilayer laminates. The substrate may be masked to provide a layout for the laminate that corresponds to the desired conductivity pathway for at least a portion of the microcircuit.

The laminate may be in electrical connectivity to one or more other electrical components to provide a circuit, such as a microcircuit. In some embodiments, a first laminate, such as on a substrate, can be disposed in electrical connectivity with a second shaped laminate of different configuration from the first shaped laminate to provide a portion of an electrical circuit, such as a microcircuit. The first and second laminates may be in the form of sheets or three-dimensional shaped objects.

### EXAMPLES

In a specific embodiment, the laminate structure was fabricated by growing a continuous graphene monolayer on a 1-mm thick Cu sheet (Alpha Aesar, 99.9999%) via chemical vapor deposition process at 1000° C. for 30 minutes. During the growth process, methane and hydrogen flow at 5 sccm and 10 sccm respectively while maintaining a pressure of 0.2-0.3 Torr. Next, a 100 nm layer of Cu was deposited via physical vapor deposition on the grown graphene monolayer to synthesize a Cu-Graphene-Cu laminate.

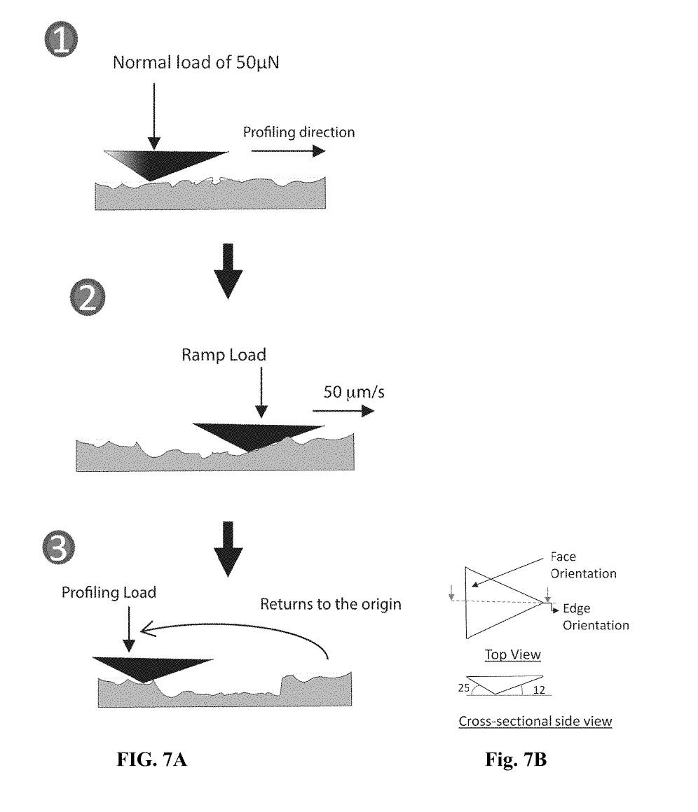

The frictional properties of the composite were measured using a scratch test method on a nanoindenter, such as a G200 Agilent nanoindenter, shown schematically in FIG. 7A. The system continuously measures the lateral forces acting on a Berkovich tip during the scratch. The Berkovich tip (1) profiles the scratch path, (2) returns to the origin and is loaded to a prescribed normal force, and (3) profiles the residual deformation along the scratch path. FIG. 7B shows schematically the shape of the Bercovich tip. Standard scratch parameters are summarized in Table 1.

TABLE 1

| Layer | Scratch | Scratch | Maximum | |
|---|---|---|---|---|
| Thickness | Velocity | Length | Scratch | Scratch |
| (nm) | (μm/s) | (μm) | Load (mN) | Orientation |
| 100 | 50 | 500 | 0.5 | Edge |
| 200 | 50 | 500 | 0.7 | Edge |
| 400 | 50 | 500 | 1.5 | Edge |

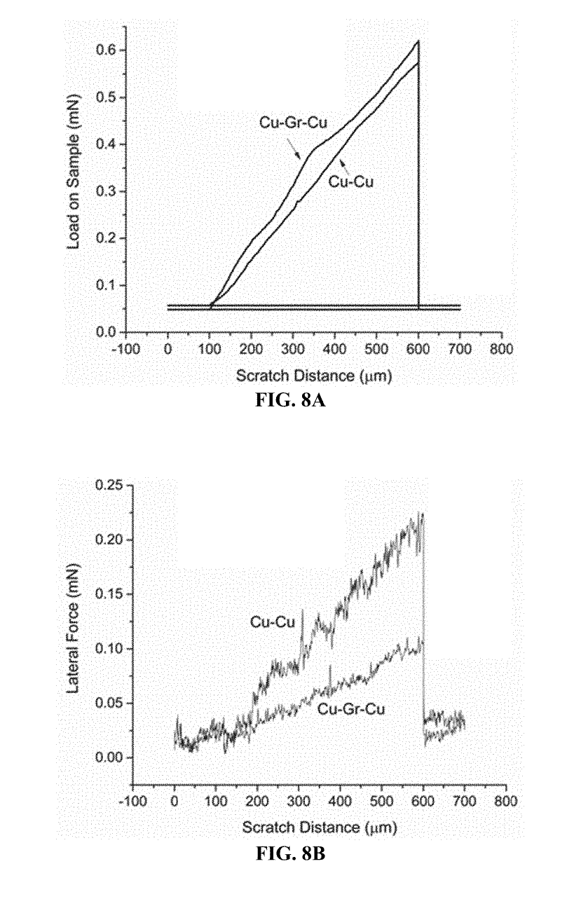

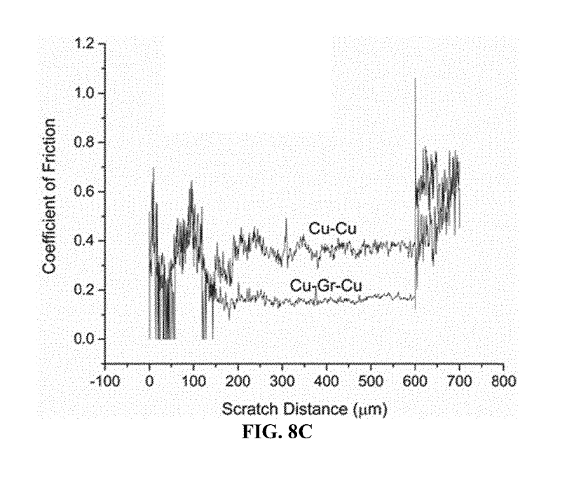

The scratch test was performed on two different samples, a Cu-Gr-Cu laminate, and a graphene-free Cu—Cu laminate. A plot of the load compared to the scratch distance for the samples is shown in FIG. 8A. A comparison of the measured lateral force and the frictional coefficient for these samples are shown in FIGS. 8B and 8C. The coefficient of friction is determined by dividing the lateral force measured by the load on the sample. FIG. 8B indicates a considerably lower measured lateral force for the Cu-Gr-Cu laminate compared to the measured lateral force for Cu—Cu laminate. Consequently, we obtained a corresponding reduction in the friction of coefficient (CoF) from 0.4 to 0.2 for a Cu-Gr-Cu laminate. A lower measured friction of coefficient corresponds to lower energy dissipation during the scratch segment and consequently a lower degree of plastic deformation in the Cu-Gr-Cu laminate. Less force is required for the tip to plow through the material at the same scratch velocity. There is a greater resistance at the graphene interface to dislocation transmission. These results suggest that the graphene sheet impedes the propagation of the plastic zone from the contact to the subsequent copper layer, thereby improving the wear resistance of the composite. The laminate exhibits greater scratch hardness.

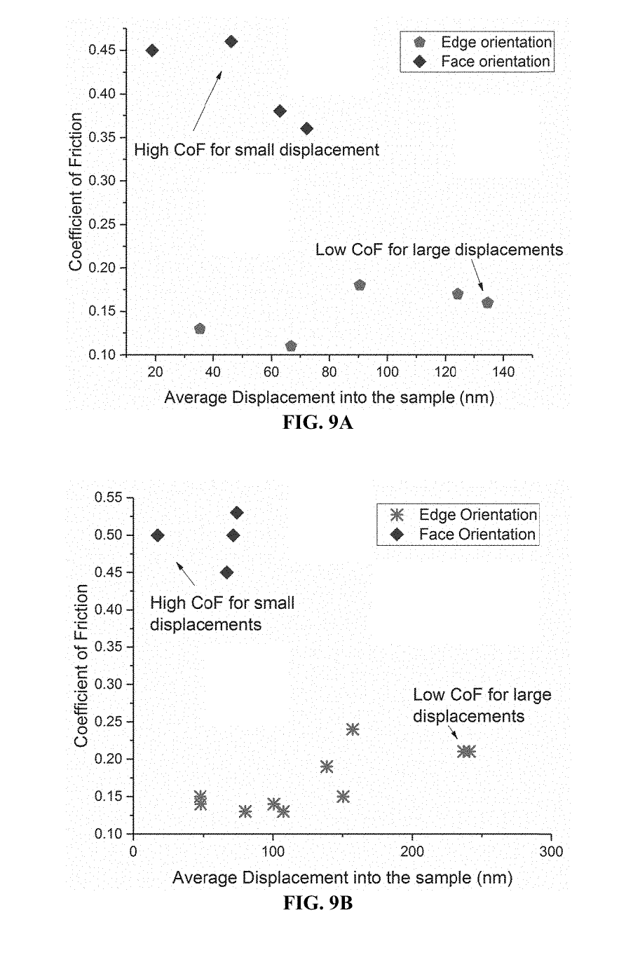

Scratch tests along the face orientation have a higher CoF compared to the edge orientation for a similar average displacement into the surface, as shown in FIGS. 9A and 9B for Cu-Gr-Cu laminates having copper top layers of 300 nm and 400 nm respectfully. The last two points of the graphs correspond to loads greater than the load leading to intefacial failure (3 mN and 4 mN). The difference in the results is related to the tip geometry during the tests. The face orientation presents a broader orientation than the tip orientation. True contact between asperities is generally smaller than the apparent contact. It is at true contact that the kinetic energy due to sliding is dissipated. The CoF can then depend on the interaction between these asperities. The asperities undergo plastic deformation as the tip slides forward. Because of adhesion, the larger number of asperities encountered by the tip in its face orientation, greater frictional force would need to be overcome for the tip to move forward.

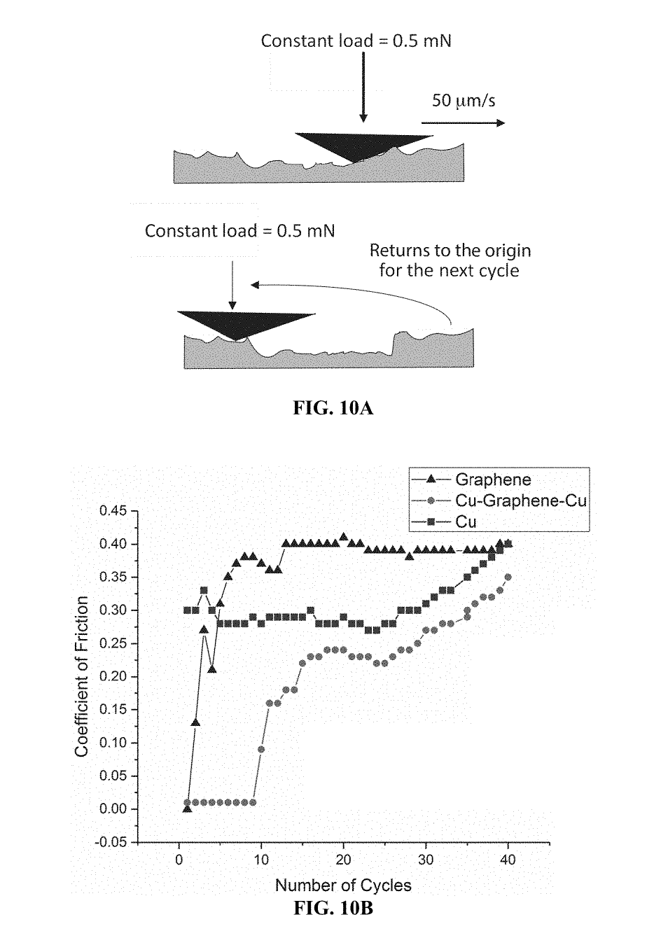

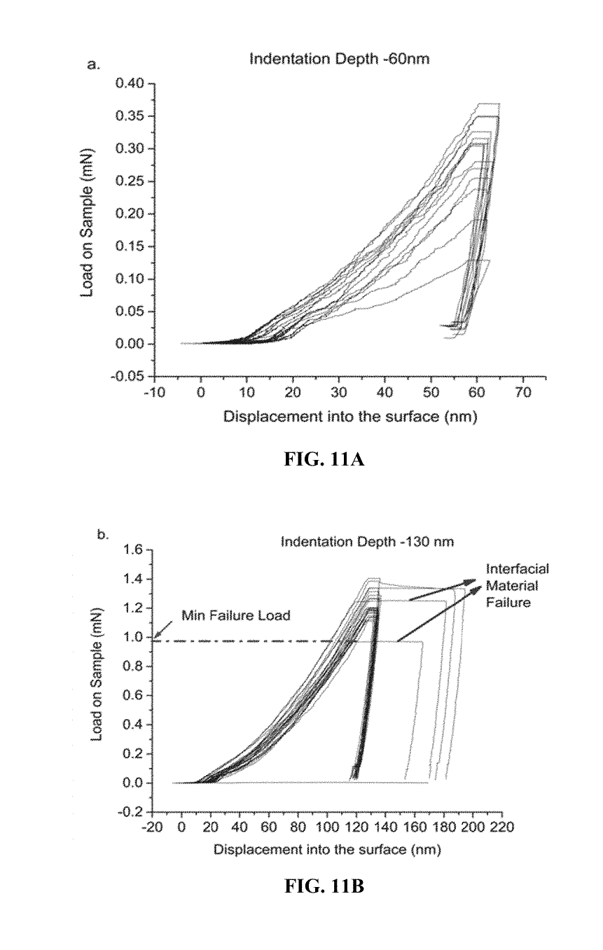

A Cu-Gr-Cu laminate structure shows an increased resistance to wear compared to a bare copper structure (no graphene) and a graphene-coated structure. The schematic of this test is shown in FIG. 10A and a graph of the coefficient of friction vs. number of cycles is shown in FIG. 10B. The bare copper structure starts at a plateau with a coefficient of friction of about 0.3 for about 30 cycles, which gradually increases to about 0.4 from 30 to 40 cycles. The graphene-coated structure reaches a plateau of about 0.4 in less than about 10 cycles. The graphene coating tears easily, and the graph suggests that the wear on the graphene-coated structure may be largely due to wear of the exposed copper substrate. In contrast, the Cu-Gr-Cu laminate exhibits a significantly lower coefficient of friction (almost 0) for about 10 cycles before gradually climbing to a coefficent of friction of about 0.35 at 40 cycles, which is less than the bare Cu structure or the graphene-coated copper structure. The copper nanolayer protects the graphene from tearing, while the graphene monolayer reduces dislocations in the overlying copper nanolayer.

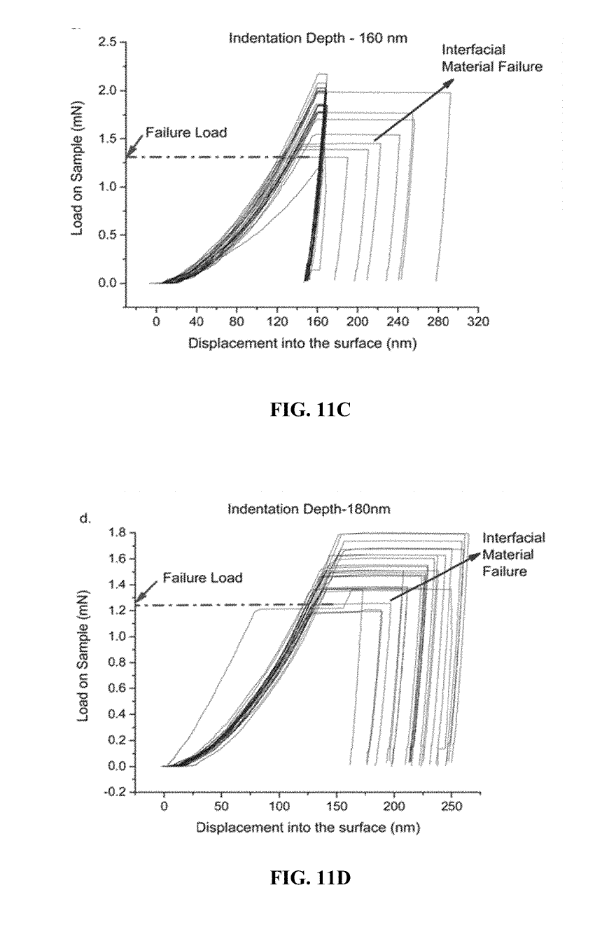

FIGS. 11A-11C show aspects of nano-indentation tests on a Cu-Gr-Cu laminate having a 300 nm copper surface layer. A series of shallow indents of up to 130 nm were applied to the laminate. The tests indicate a Young's modulus of 220 GPa and a hardness of 5 GPa.

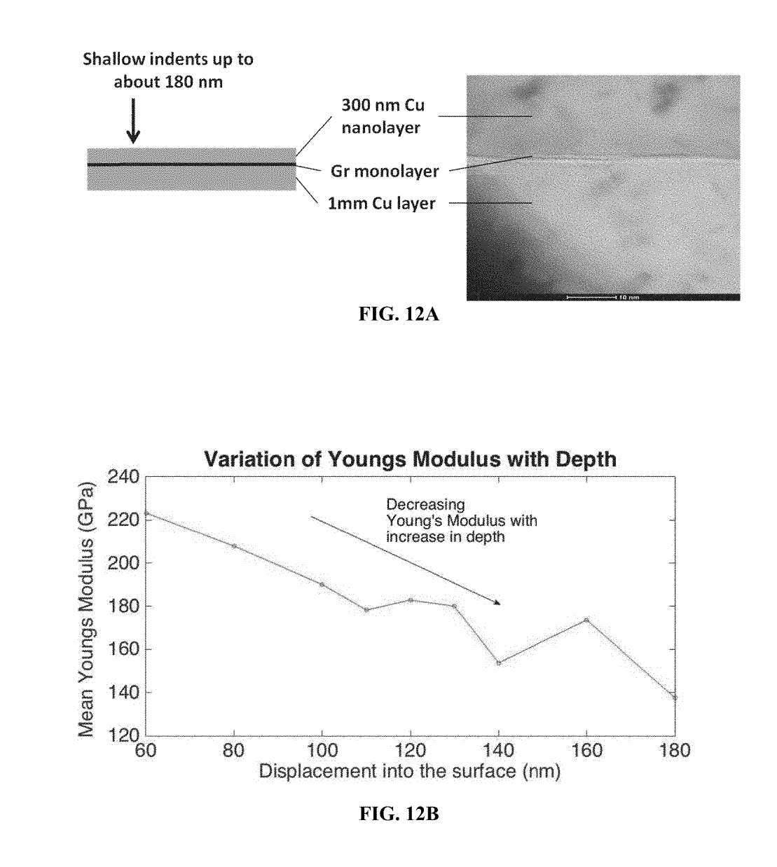

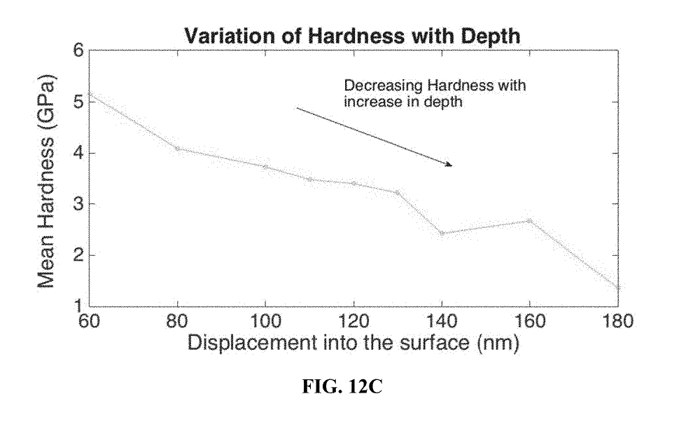

The load displacement curve for a series of shallow indents is shown in FIGS. 12A to 12D. Specifically, the load displacement curves shown in these figures represents a series of depth controlled shallow indentations performed for depths ranging from 60 nm to 180 nm on a Cu-Gr-Cu laminate having a 100 nm copper nanolayer. These indicate that the laminate exhibits an increased tendency of interfacial material failure (plateau region) for normal loads greater than 500 μN.

While the disclosed subject matter has been described in terms of particular variations and illustrative figures, those of ordinary skill in the art will recognize that the disclosed subject matter is not limited to the variations or figures described. In addition, where methods and steps described above indicate certain events occurring in certain order, those of ordinary skill in the art will recognize that the ordering of certain steps may be modified and that such modifications are in accordance with the variations of the disclosed subject matter. Additionally, certain of the steps may be performed concurrently in a parallel process when possible, as well as performed sequentially as described above. Therefore, to the extent there are variations of the disclosed subject matter, which are within the spirit of the disclosure or equivalent to the disclosed subject matter found in the claims, it is the intent that this patent will cover those variations as well.

What is claimed is:

1. A laminate comprising:
a base layer comprising copper;
a graphene monolayer disposed on the base layer; and
a top layer comprising copper disposed on the graphene monolayer;
wherein the laminate exhibits a reduced coefficient of friction in comparison to a copper-copper laminate without a graphene monolayer.

2. The laminate of claim 1 wherein the top layer has a thickness from 50 to 500 nm.

3. The laminate of claim 1 further comprising an additional graphene monolayer disposed on the top layer and an additional copper layer disposed on the additional graphene monolayer.

4. The laminate of claim 1 further comprising one or more additional substrate layers on which the copper base layer is superimposed.

5. The laminate of claim 4 wherein additional substrate layers comprises a bulking or backing layer wherein the base layer of copper has a thickness from 50 to 500 nm.

6. The laminate of claim 4 wherein the one or more additional substrate layer comprises a material selected from the group consisting of a metal other than copper, nonconductive materials, or semiconductor materials.

7. The laminate of claim 1 in the form of a sheet.

8. The laminate of claim 1 in the form of a three-dimensional shaped object.

9. The laminate of claim 1 used as an electrical connector.

10. The laminate of claim 1 wherein the laminate comprises a portion of an electrical circuit.

11. The laminate of claim 10 wherein the laminate comprises a portion of microcircuit.

12. The laminate of claim 1 wherein the laminate comprises a portion of a microchip.

13. The laminate of claim 1 in electrical connectivity to one or more other electrical components to provide a circuit.

14. The laminate of claim 13 wherein the circuit comprises a microcircuit.

15. The laminate of claim 1 wherein a first laminate is disposed in electrical connectivity with a second laminate of different configuration from the first laminate to provide a portion of an electrical circuit.

16. The laminate of claim 15 wherein the first and second laminates are in the form of sheets.

17. The laminate of claim 15 wherein a first shaped laminate is disposed in electrical connectivity with a second shaped laminate of different shape from the first shaped laminate to provide a portion of an electrical circuit.

18. A laminate comprising n graphene monolayers and n+1 copper layers, wherein the graphene monolayers alternate with the copper layers, and n is an integer from 1 to 10.

19. The laminate of claim 18 wherein one of the copper layers comprises a thicker substrate layer, and the rest of the copper layers are nanolayers, each having a thickness from 50 to 500 nm.

20. The laminate of claim 18 wherein the substrate layer is a surface layer.

21. The laminate of claim 18 wherein the substrate layer is the center layer of the laminate.

22. The laminate of claim 18 comprising one or more additional layer.

23. A method for preparing a laminate of claim 1, the method comprising:
providing a base layer comprising copper;
disposing a graphene monolayer on the base layer; and
disposing a top layer comprising copper on the graphene monolayer.

24. The method of claim 23 wherein disposing the graphene monolayer on the base layer comprises chemical vapor deposition of carbon atoms on the base layer.

25. The method of claim 23 wherein disposing the top layer comprising copper on the graphene monolayer comprises physical vapor deposition of copper atoms on the graphene monolayer.

26. The method of claim 23 further comprising electropolishing the base layer prior to disposing the graphene monolayer on the base layer.

27. The method of claim 23 further comprising sequentially disposing at least one additional graphene monolayer on the top layer; and disposing at least one additional layer comprising copper on the at least one additional graphene monolayer to provide a laminate comprising alternating graphene monolayer and copper layers on the base layer.

28. A method for improving the wear performance or reducing friction of an electrical connector, the method comprising:
providing a base layer comprising a copper electrical connector;
disposing a graphene monolayer on the base layer;
and disposing a top layer comprising copper on the graphene monolayer.

29. The method of claim 28 wherein disposing the graphene monolayer on the base layer comprises chemical vapor deposition of carbon atoms on the base layer.

30. The method of claim 28 wherein disposing the top layer comprising copper on the graphene monolayer comprises physical vapor deposition of copper atoms on the graphene monolayer.

31. The method of claim 28 further comprising electropolishing the base layer prior to disposing the graphene monolayer on the base layer.

32. The method of claim 28 further comprising sequentially disposing at least one additional graphene monolayer on the top layer; and disposing at least one additional layer comprising copper on the at least one additional graphene monolayer to provide a laminate comprising alternating graphene monolayer and copper layers on the base layer.
